(19) United States
(12) Patent Application Publication
(10) Pub. No.: US 2025/0107311 A1
(43) Pub. Date: Mar. 27, 2025

(54) SEMI-TRANSPARENT SOLAR MODULES, AND APPLICATIONS THEREOF

(71) Applicant: Rudi DANZ, Kleinmachnow (DE)

(72) Inventor: Rudi DANZ, Kleinmachnow (DE)

(21) Appl. No.: 18/832,040

(22) PCT Filed: Nov. 9, 2022
(86) PCT No.: PCT/DE2022/000110

§ 371 Date: Jul. 22, 2024

(30) Foreign Application Priority Data
Feb. 5, 2022 (DE) 20 2022 000 302.1

(51) Int. Cl. H10K 30/87

(52) U.S. Cl. CPC H10K 30/87

(57) ABSTRACT

Semi-transparent solar modules for efficient generation of electrical energy as electricity-supplying and partially transparent canopies consisting of solar cells and functional layers alternately applied to glass and other optically transparent substrates, the functional layers being both partially transparent and scattering incident solar radiation, guiding it to the solar cells and for lighting purposes under the modules, and protecting agricultural crops and soils 10 from frost, drought and desiccation as well as heat and promoting plant growth.

The invention relates to solar modules for generating electrical energy from solar radiation and their applications. Solar modules consist of solar cells which efficiently generate electric power by solar radiation. The solar cells are arranged so densely on the solar modules that the module surfaces are completely covered, and in this way, maximum electrical power can be generated. Semi-transparent or partially transparent solar modules for the roofing of conservatories, as canopies, as skylights or on carports ensure that, on the one hand, electrical solar energy is generated and, on the other hand, the rooms located under the solar modules are shaded and supplied with sufficient light. In the production of semi-transparent solar modules, cell gaps around the cell, e.g. from 5 mm to 50 mm, are allowed when parqueting the solar cells on the glass substrates, so that light can penetrate into the rooms below through the areas on the glass substrates that are free of the solar cells. Depending on the size of the cell spacing, reasonable light transmissions of 10% to 60% can be set. It is also possible to arrange the solar cells on the glass substrates in strips (www.ertex-solar.at, www.solarcarporte.de, htts://en.gridparityag.com, https://www.solarwende-berlin.de, DE 202011107554U1). Semi-transparent solar modules also allow the generation of solar electricity on agricultural land and on greenhouses and at the same time the growth of fruit under the modules (WO2002005352A3, US20090277500A1, DE102020118210A1). The shading caused by the modules protects the soil and prevents it from drying out. Thin-film solar modules based on cadmium telluride and organic solar cells also serve as semi-transparent solar modules. The solar cells themselves are partially translucent with a relatively low efficiency of about 10%. With a transparency of 10%, performance losses of up to 14% can be expected (www.sanko-solar.de, https://solarenergie.de). Semi-transparent thin-film solar modules, in which active non-transparent solar cells alternate with areas free of solar cells, are used especially on facades (EP 3039718A1). Dye-sensitised thin-film modules are used in greenhouses to operate temperature and humidity sensors. With a transparency of 35%, they have an efficiency of approx. 3.8% Semi-transparent thin-film (https://doi.org/10.3390/de14196393). modules with a cell occupancy of 10% to 100% based on organic and inorganic nanostructured solar-active composite materials are used in greenhouses, whereby the necessary photosynthetically active visible radiation and the electrical power generated by the modules are optimised. The electrical power generated is used for air-conditioning the greenhouses and for operating hydroponics (https://www.britesolar.com). Thin-film solar modules with organic polymers are semi-transparent and supply greenhouses with light and generate electricity with an efficiency of about 7% (https://www.polysolar.co.uk). Semi-transparent thin-film modules as windows and for facades have a high transparency for visible light and use infrared and ultraviolet light to generate solar electricity. They are intended as solar glazing for buildings and have an efficiency of about 10% (https://ubiqitous.energy, http://www.solar-constructions.com, EP 2254153A1, U.S. Pat. No. 7,795,067B1).

The listed technical solutions to the state of the art are fraught with a number of disadvantages. In the case of efficient semi-transparent silicon solar modules, in which solar cells and free areas alternate on the modules, the basic problem is that the more light is required under the solar modules, the fewer solar cells can be placed on the modules. This means that light transmission and electricity yield are in opposition to each other. If, for example, the modules are fitted with one-third fewer solar cells due to the need for high light transmission under the solar modules, the yield of the achievable electrical solar energy is also reduced by at least one-third. In the case of semi-transparent solar modules with alternating solar cell/free-space occupancy, there is an uneven distribution of light under the modules because no direct light can get under the solar cells. The resulting non-uniformity in the light distribution under the modules is particularly disadvantageous when a nearly uniform light distribution is required, e.g. in horticultural and agricultural applications. Thin-film solar modules have a relatively high and evenly distributed transmission, but their efficiency is usually below 10%. This means that too little electrical energy is generated when they are used, so that the capital expenditure for their application is often not justified.

According to the invention, the task is to provide semi-transparent solar modules with the necessary high transparency and uniform illumination of the spaces under the modules with high electrical power and the lowest possible investment costs.

According to the invention, the task is solved by applying opaque and/or spectrally semi-transparent solar cells of high efficiency at a distance of 5 mm to 100 mm-preferably of 60 mm-to solar glass or other optically transparent substrates and covering the resulting areas free of solar cells (also called free areas) with optically functional layers which ensure the required optical transparency of the modules and which are equipped with additional functions advantageous for the solar modules according to the invention. The optically functional layers applied to the free surfaces have a multiple function of partially and spectrally transmitting the incident solar radiation, scattering light and guiding a portion of the radiation to the solar cells and spectrally converting the incident solar radiation. In a first embodiment of the invention, partially transparent and light-scattering layers are first applied to the back of the solar glass substrates as functional layers, which either transmit incident solar radiation into the lower spaces and/or reflect it back into the solar glass and optically guide it there. The partially transparent and light-scattering layers consist of a binder containing light-scattering particles such as titanium dioxide, barium sulphate or ceramic pigments. In the production of the light-scattering and light-conducting semi-transparent layers on the free surfaces of the glass substrate, reflector inks are preferably used by means of screen-printing processes or spraying techniques, which contain, for example, barium sulphate, calcium carbonate and/or titanium dioxide combined with talcum powder as scattering particles, and their proportion by weight in relation to the binder material is between 10% and 30%, preferably 20%. The incident solar radiation hits the light-scattering particles, where it is scattered and, on the one hand, penetrates the binder layer and enters the lower spaces and, on the other hand, is optically isotropically reflected back into the solar glass substrate and, as a result of total reflection, reaches the solar cells in a broadband light-conducting manner by optically coupling into the solar cells. Total reflection within the solar glass substrate occurs because at the interface between glass and air there is a transition from an optically denser medium (glass) to an optically thinner medium (air). If the composition of the light-scattering and light-conducting layers is optimal with regard to the type and concentration of the scattering particles and their thickness, the incident solar radiation is both transported through the layers with the necessary transparency and is totally reflected spectrally inside the solar glass substrate over a broad band at an angle greater than the critical angle of total internal reflection and is guided to the solar cells by light conduction with high efficiency. The light-scattering layers are to be designed by adding talc to the polymer binder so that the incident solar radiation is scattered flatly at large angles relative to the incidence slot and thus a large proportion is totally reflected and reaches the solar cells. In an advantageous embodiment of the invention, pigments with a weight concentration of 1% to 10% are also used for the light-scattering and light-transporting layers, which allows that the layers in the visible spectral range from 400 nm to 700 nm largely let the solar radiation through (transparency greater 15 than 60%) and conduct it under the modules, while in the NIR (near infrared) range from 700 nm to 2 μm there is low transparency (20% to 30%) and high diffuse spectral reflection of up to 80% to 90%. The pigments used consist of a transparent carrier material based on thin platelets of silicate minerals (mica), which are coated in a single 20 layer with highly refractive materials of titanium dioxides, zinc oxides, cerium oxides, etc. or in several layers with optically highly refractive materials followed by low refractive materials, e.g. of silicon dioxide, aluminium oxide, etc. By special selection of the pigments, the optical properties of the light-scattering and light-transporting layers can be specifically adjusted with regard to transmission and reflection in the spectral range 400 nm to 700 nm and 700 nm to 2 μm. The pigments of choice are Iriotec 9770, 9230, 9880 and 9875 as well as Iriodine SHR 875 and 9875 (Merck KGaA, Bodo Möller Chemie GmbH). The special features and advantages of the described embodiment of the invention are that the spectrum of the solar radiation is divided by the use of the special pigments: the largest part of the visible range of the radiation gets under the modules, serves the plant growth and lighting purposes, the NIR range is reflected to a high degree diffusely and reaches the solar cells as a result of total reflection in the solar front glasses and produces an additional yield of electrical power there as a result of radiation amplification. The supply of additional NIR radiation to the solar cells has a positive effect on solar power generation in that highly efficient solar cells have a high spectral sensitivity in the NIR range. The design of the light-transporting and light-scattering layers shown in accordance with the invention makes it possible to strongly promote the growth of plants and other crops under the modules and, on the other hand, to protect the crops and soils from drying out and heat by keeping the heat out through the strong NIR reflection and allowing the visible radiation necessary for the growth of the crops to pass through and, in addition, to efficiently generate solar energy. Interior spaces under the modules (e.g. conservatories, shopping arcades, etc.) are also protected from heat and well lit.

In addition to the partially transparent light-scattering and light-conducting layers applied to the back of the solar glass substrates, fluorescent layers that convert short-wave solar radiation into longer-wave radiation are applied there to increase the transparency and electrical output of the modules according to the invention. In particular, this technology converts UV radiation, which is not suitable for illuminating the spaces under the modules and which cannot be converted into solar energy by most solar cells, into longer-wave visible radiation, with advantages for the generation of solar power and for an increased light yield under the modules. The spectrally light-converting fluorescent layers consist of organic fluorescent dyes and/or inorganic fluorescent pigments of high fluorescence quantum yield and photostability, which are incorporated in optically transparent polymer binders, such as polyacrylate, with a weight fraction of 0.5% to 3%—preferably 1%—based on the binder material. Suitable fluorescent dyes are, for example, photostable xanthenes, rhodamines, pyrromethenes, perylenes or naphthalimides. Inorganic fluorescent pigments used are, for example, phosphors from the group of rare earth metals, doped phosphates or silicates and germanates. LED phosphors that convert short-wave radiation into longer-wave radiation are also suitable for the fluorescent layers. Red LED phosphors based on europium-doped lutetium tantalates with fluorescence emissions in the range of 600 nm to 700 nm are efficiently used as spectral light converters. When incident solar radiation hits the fluorescent layers, it is absorbed there in the short-wave range, and optically isotropic longer-wave fluorescent radiation is emitted. The generated isotropic fluorescence radiation and the radiation outside the absorption band of the fluorescent dye penetrate the fluorescent layer and reach the spaces below the module. On the other hand, the emitted fluorescence radiation enters the glass substrate from the fluorescence layer and, due to its isotropy, is optically guided by total reflection along the thickness of the glass substrate by multiple reflection in a zig-zag course, reaches the solar cells, where it is coupled into the solar cells and there leads to light amplification and thus to an increase in the electrical output of the solar cells. With optimal composition of the functional light-scattering and fluorescent layers, 30% to 50% of the solar radiation incident on the layers is conducted to the solar cells, where it additionally increases the electrical output. An advantageous embodiment of the invention is to allow a multi-layer system as functional layers and to first apply the fluorescent layer and then the light-scattering reflector layer to the glass substrates. Incident solar radiation then first hits the fluorescent layer, is spectrally converted and reaches the solar cells at least partially as emitted radiation. The spectrally incoming solar radiation outside the absorption band penetrates the fluorescent layer and hits the light-scattering layer, from where it is either transported into the lower spaces or directed to the solar cells. This ensures optimal processing of the incident solar radiation in terms of light amplification at the solar cells and transmission. In order to ensure optimal functioning of the semi-transparent solar modules according to the invention with regard to electrical power, transparency and uniformity of illumination under the modules, the width of the functional layers should be adjusted to the required transparency of the modules and the thickness of the layers should be selected in the range of 20 μm to 100 μm, preferably 50 μm. The areas free of solar cells on the glass substrates are designed in the form of strips, with solar cell strings arranged as strips alternating with strip-shaped areas free of solar cells and covered with functional layers, whereby their width varies between 5 mm and 100 mm with preferred widths of 50 mm. This results in a lamellar arrangement of solar cells and surfaces free of solar cells. In another variation, the free areas are located around the individual solar cells, whereby the resulting strips between adjacent cells also have a width of 5 mm to 100 mm, preferably 50 mm. With the shown widths of the functional layers, transparencies of the semi-transparent modules according to the invention of 60% and more can be set in the visible spectral range. The optimum width of the functional layers also determines the amplification of the radiation and thus the current yield at the solar cells by controlling the intensity of the additional radiation directed to the solar cells. Furthermore, it is advantageous to use half cells with dimensions of 78 mm*156 mm in the production of the solar modules. By using half cells, the optical path of the light scattered to the solar cells and the emitted fluorescent radiation is halved, thus reducing their optical losses and allowing more radiation to reach the solar cells with an advantage for their generated electrical power. Also advantageous in the sense of the invention is the use of bifacial solar cells, which can also convert solar radiation under the modules into electricity. After applying the solar cells and the functional layers to the solar glass substrates, the modules according to the invention are completed to form glass-glass and glass-foil modules. The functional layers, like the solar cells, are applied to the back of the solar glass substrates and are thus protected from the weather by the glass substrates. In the case of glass-glass modules, solar radiation scattered in the rear glass also spreads out, reaches the rear sides of the solar cells and, in the case of bifacial solar cells, contributes to electricity generation.

The semi-transparent solar modules according to the invention have the advantage that not only solar radiation, which is directly directed to the solar cells, contributes to the solar power, but that additional radiation is supplied to the solar cells through the functional layers applied to the modules, which leads to an intensification of radiation and thus to an additional yield of solar power. The functional layers have a double function here: on the one hand, they contribute to an increased solar output, and on the other hand, through their special design, a defined transmission can be set that meets the lighting requirements in the spaces under the solar modules in terms of brightness, uniformity of illumination and shading. Compared to conventional semi-transparent modules, the solar modules according to the invention have the advantage that they generate 10 to 25% more solar power due to the radiation amplification at their solar cells. In relation to the generated solar power, this means a 10 to 25% saving on solar cells and materials for electrical contacts and lines. Since the costs for the functional layers used on the solar modules according to the invention, which lead to the aforementioned radiation intensification at the solar cells, amount to a maximum of 10% of the costs for the solar cell expenditure, the application of the solar modules according to the invention leads to a significant cost saving and thus to a reduced investment expenditure combined with material savings. Furthermore, due to the character of the diffuse reflecting layers contained in the modules, a certain radiation cooling occurs at the solar modules according to the invention, because infrared radiation is reflected out of the solar glass within the loss cone formed by the limiting angle of total reflection and thus does not contribute to the heating of the modules with advantages for the power efficiency of the modules.

The semi-transparent solar modules according to the invention find advantageous applications as power-supplying roofing for solar terraces, in conservatories, on stadiums, shopping arcades, as canopies, as skylights, on carports, on greenhouses and agricultural areas or also on traffic routes (roofing of motorways) and parking areas. In addition to an efficient electricity yield, they provide shade and uniform illumination. As roofing on motorways, they provide sufficient brightness under the modules and at the same time supply electrical solar power for their illumination and ice control as well as for electric mobility. On greenhouses or in agriculture, they guarantee favourable plant growth due to the uniform illumination and shading under the modules and the emission of coloured light in the photosynthetically active blue and red spectral ranges, and provide electrical power for their air-conditioning and heating purposes. Due to their covering properties, the semi-transparent modules protect against frost in the transitional periods and against drying out and drought in summer. In the case of a coloured design of the invention, it is also used on facades for buildings and boundaries. For the applications mentioned, the modules according to the invention also have the advantageous property that they are 10% to 20% lighter than comparable modules of the same electrical output, because they contain fewer solar cells and conductor material. This means that costs can be saved when they are installed, for example, above agricultural and parking areas or above motorways or on greenhouses. The solar modules according to the invention can also be advantageously mounted in the form of a folding bridge, which is automatically folded up when the ground is worked or when it rains.

### DESIGN EXAMPLE

For the production of the semi-transparent solar modules, monocrystalline silicon solar cells are arranged as solar cell strings in strips on the solar glass substrate, whereby strip-shaped free areas with a width of 60 mm are allowed between the solar cell strings, which represent the distances between the cells. The edges of the solar glass are also left free of solar cells, so that all strings are surrounded by free areas. Silicon half cells with a width of 78 mm are used as solar cell strings. The areas remaining free of solar cells on the solar glass are covered with partially transparent, light-scattering and light-conducting functional layers, which on the one hand allow the radiation to pass through the layers and on the other hand guide it to the solar cells. For this purpose, matt white reflective lacquers containing light-scattering particles are applied to the free surfaces by screen printing. Matt, white and highly reflective paints, which are also used as camouflage paints, have proven to be particularly suitable for this purpose. They reflect the solar radiation over a broad band in the visible spectral range as well as strongly diffusely in the near infrared spectral range, which is important for silicon solar cells, and guide it efficiently in the glass substrate to the solar cells. The layer thickness of the light-scattering and partially transparent coatings is set to approx. 30 μm, which results in an optical transmission of the applied layers of approx. 40%. By integrating free areas with partially transparent and light-scattering layers on the solar cell glass substrates, it is possible in this case to realise semi-transparent solar modules which, as a result of their radiation amplification at the solar cells, have a 10 to 20% higher electrical output than corresponding comparison modules with a given optical transparency. In one embodiment of the semi-transparent solar modules, layers with a fluorescent violet lacquer based on naphthalimide are first applied to the free surfaces of the glass substrates. Then a matt reflective lacquer is applied. The fluorescent violet lacquer layer applied first is reached first by the solar radiation and converts the invisible UV component contained in the solar radiation into visible light and causes light amplification and increases the optical transmission of the coatings. For the coloured design of the semi-transparent solar modules, optically transparent fluorescent lacquers, such as fluorescent lacquer yellow, orange or red based on highly fluorescent perylenes, are used in the production of functional layers. The resulting fluorescent layers are optically transparent outside their absorption bands and thus ensure the transmission of coloured light, which can be used specifically to stimulate plant growth, through the module. On the other hand, they generate isotropic fluorescence radiation that penetrates the glass substrate and is emitted by light conduction.

1-4. (canceled)

5. Semi-transparent solar modules for the generation of electrical energy, where the solar modules solar glass-substrates or other optically transparent substrates exhibit, are characterised in that on the back of the solar glass substrates or other optically transparent substrates opaque and/or spectrally partially transparent solar cells alternating with optically functional layers which are both partially transparent and transport the solar radiation through the modules and also scatter incident solar radiation and conduct it to the solar cells and which spectrally convert short-wave light of the incident solar radiation into longer-wave light, the area of the functional layers on the optical substrates being 20% to 50%, preferably 40%, and the functional layers having a spectral transmission in the range from 400 nm to 700 nm of greater than 60% and between 700 nm and 2 um a transmission of 10% to 30% and a diffuse reflection of 70% to 90%.

6. Semi-transparent solar modules according to claim 1, wherein the optically functional layers consist of reflector coatings containing light-scattering particles based on titanium dioxide, barium sulphate, calcium carbonate and platelet-shaped silicate materials (mica) as well as talc in suitable binder materials and/or are composed of fluorescent layers with fluorescent materials selected from the group of organic fluorescent dyes such as xanthenes, rhodamines, oxazines, perylenes, pyrromethenes and naphthalimides and selected from the group of inorganic fluorescent pigments, such as e.g. Rare earth metal phosphors, doped phosphates or silicates or also LED phosphors.

7. Semi-transparent solar modules according to claim 1 for use as power-supplying and light-guiding semi-transparent canopies for solar terraces, conservatories, canopies, skylights, carports, greenhouses, shopping arcades, stadiums and agricultural areas, motorways and other traffic routes, car parks and as coloured facades on buildings and boundaries.

8. Semi-transparent solar modules according to claim 1 for thermal protection and for the illumination of indoor spaces, for the protection of agricultural crops and soils against frost, dehydration, damaging solar radiation and heat, and for promoting plant growth.
